(19) United States
(12) Patent Application Publication
(10) Pub. No.: US 2026/0213137 A1
(43) Pub. Date: Jul. 23, 2026

(54) SUSCEPTOR AND PLASMA PROCESSING APPARATUS COMPRISING THE SAME

(71) Applicant: SAMSUNG ELECTRONICS CO., LTD., Suwon-si (KR)

(72) Inventors: Dohyung Kim, Suwon-si (KR); Minseob Kim, Suwon-si (KR); Minsu Lee, Suwon-si (KR); Seungwon Noh, Suwon-si (KR); Jeongho Mun, Suwon-si (KR); Yejin Shon, Suwon-si (KR); Changyun Lee, Suwon-si (KR); Minsoo Jeon, Suwon-si (KR)

(73) Assignee: SAMSUNG ELECTRONICS CO., LTD., Suwon-si (KR)

(21) Appl. No.: 19/316,211

(22) Filed: Sep. 2, 2025

(30) Foreign Application Priority Data
Jan. 22, 2025 (KR) 10-2025-0009822

(51) Int. Cl. H01J 37/32

(52) U.S. Cl. CPC H01J 37/32715; H01J 37/32642; H01J 37/32834

(57) ABSTRACT

Provided is a susceptor including a susceptor body, a top surface of the susceptor body configured to support a wafer, an edge ring spaced apart from the top surface of the susceptor body in a vertical direction, the edge ring having a circular ring shape, and a plurality of support pins between the top surface of the susceptor body toward a bottom surface of the edge ring, wherein a central axis of the edge ring is the same as a central axis of the susceptor body, an outer diameter of the edge ring is less than or equal to a diameter of the susceptor body, and an inner diameter of the edge ring is greater than a diameter of the wafer, wherein a thickness of each support pin of the plurality of support pins in the vertical direction is greater than or equal to 0.3 mm, and wherein a level of a top surface of the edge ring is greater than a level of a top surface of the wafer in the vertical direction.

### CROSS-REFERENCE TO RELATED APPLICATION

This application claims priority to Korean Patent Application No. 10-2025-0009822, filed on Jan. 22, 2025, in the Korean Intellectual Property Office, the disclosure of which is incorporated by reference herein in its entirety.

### BACKGROUND

Embodiments of the present disclosure relate to a plasma processing apparatus, and more particularly, to a susceptor supporting a wafer and a plasma processing apparatus including the same.

In various plasma processing processes, an edge ring on the outer area of the susceptor may be provided to ensure uniform plasma processing over the entire area of the wafer.

However, since the edge ring is placed in the outer area of the susceptor, particles, such as ions and/or radicals, may be stagnant without being smoothly discharged to the outside of the edge ring. Due to the stagnation of particles, plasma processing at the edge of the wafer may be very active, making it difficult to achieve uniform plasma processing over the entire area of the wafer.

### SUMMARY

One or more embodiments provide a plasma processing apparatus capable of performing uniform plasma processing over the entire area of a wafer.

One or more embodiments also provide a susceptor having a uniform exhaust capacity in a radial direction.

According to an aspect of one or more embodiments, there is provided a susceptor including a susceptor body, a top surface of the susceptor body configured to support a wafer, an edge ring spaced apart from the top surface of the susceptor body in a vertical direction, the edge ring having a circular ring shape, and a plurality of support pins between the top surface of the susceptor body toward a bottom surface of the edge ring, wherein a central axis of the edge ring is the same as a central axis of the susceptor body, an outer diameter of the edge ring is less than or equal to a diameter of the susceptor body, and an inner diameter of the edge ring is greater than a diameter of the wafer, wherein a thickness of each support pin of the plurality of support pins in the vertical direction is greater than or equal to 0.3 mm, and wherein a level of a top surface of the edge ring is greater than a level of a top surface of the wafer in the vertical direction.

According to another aspect of one or more embodiments, there is provided a plasma processing apparatus including a housing including a plasma processing space, a susceptor inside the housing and configured to support a wafer, an exhaust port spaced apart from a central axis of the housing in a horizontal direction, at a level lower than a level of the wafer in a vertical direction, and passing through a portion of the housing, and an exhaust pump configured to suction particles inside the housing through the exhaust port, wherein the susceptor includes a susceptor body, an edge ring on the susceptor body, a central axis of the edge ring being aligned with a central axis of the susceptor bod, and a plurality of support pins between a top surface of the susceptor body and a bottom surface of the edge ring, wherein an outer diameter of the edge ring is equal to or less than a diameter of the susceptor body, and wherein particles inside the housing are configured to be exhausted through an exhaust space formed by a top surface of the susceptor body, a bottom surface of the edge ring, and the plurality of support pins.

According to still another aspect of one or more embodiments, there is provided a plasma processing apparatus including a housing, a susceptor inside the housing, an exhaust port spaced apart from a central axis of the housing in a horizontal direction and penetrating a portion of a bottom surface of the housing, and an exhaust pump configured to suction particles inside the housing through the exhaust port, wherein the susceptor includes a susceptor body, and a plurality of region rings respectively on a plurality of regions included in a top surface of the susceptor body, a center of each region of the plurality of regions being aligned with a central axis of the susceptor body, wherein each region of the plurality of regions is a region based on an exhaust capacity distribution of the exhaust pump for an upper region of the susceptor body, wherein an exhaust capacity distribution of the exhaust pump is determined based on a relative position of the exhaust port with respect to the susceptor body, wherein a level of a bottom surface of the region ring on the region having a first exhaust capacity is less than a level of a bottom surface of the region ring on the region having a second exhaust capacity, among the plurality of regions, in the vertical direction, and wherein the first exhaust capacity is greater than the second exhaust capacity.

### BRIEF DESCRIPTION OF DRAWINGS

Embodiments will be more clearly understood from the following detailed description taken in conjunction with the accompanying drawings in which:

FIG. 1 is a cross-sectional view of a plasma processing apparatus according to one or more embodiments;

FIG. 2 is a perspective view of a susceptor according to one or more embodiments;

FIG. 3 is a cross-sectional view illustrating a particle movement path inside the plasma processing apparatus, according to one or more embodiments;

FIG. 4 is a diagram illustrating exhaust capacity distribution according to one or more embodiments;

FIG. 5 is a diagram of a plurality of divided regions according to one or more embodiments;

FIG. 6 is a perspective view of the susceptor according to one or more embodiments;

FIG. 7 is a cross-sectional view of the susceptor taken along line I-I′ in FIG. 6;

FIGS. 8A, 8B, and 8C are cross-sectional views of an edge ring and support pins, according to one or more embodiments;

FIG. 9 is a diagram of a plurality of divided regions according to one or more embodiments;

FIG. 10 is a perspective view of the susceptor according to one or more embodiments;

FIGS. 11A, 11B, and 11C are cross-sectional views of the edge ring and support pins, according to one or more embodiments;

FIGS. 12A, 12B, 12C, and 12D are cross-sectional views of the edge ring and support pins, according to one or more embodiments; and

FIG. 13 is a cross-sectional view of a plasma processing apparatus according to one or more embodiments.

### DETAILED DESCRIPTION

Hereinafter, embodiments are described in detail with reference to the accompanying drawings. The same reference numerals are used for the same components on the drawings, and redundant description thereof is omitted.

Herein, a horizontal direction may include a first horizontal direction (X direction) and a second horizontal direction (Y direction) that intersect with each other. A direction intersecting the first horizontal direction (X direction) and the second horizontal direction (Y direction) may be referred to as a vertical direction (Z direction). Herein, a vertical level may be referred to as a height level in the vertical direction (Z direction) of any configuration.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

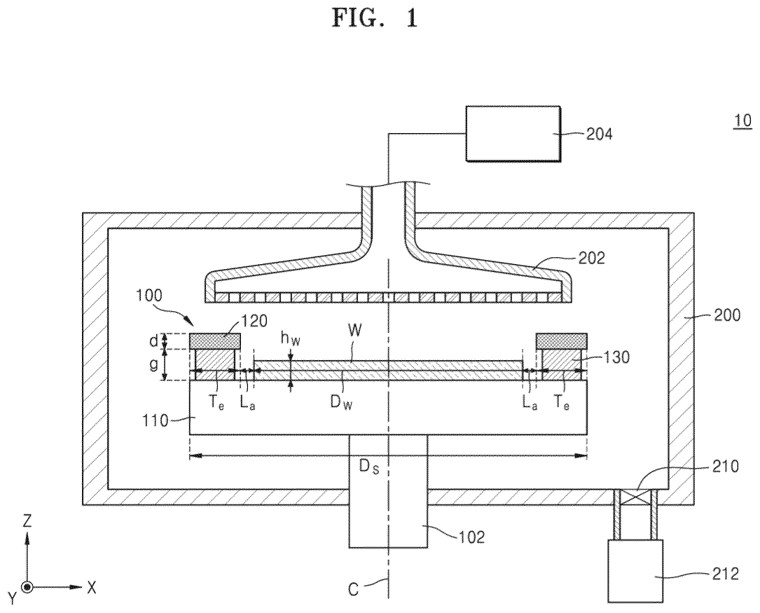

FIG. 1 is a cross-sectional view of a plasma processing apparatus 10 according to one or more embodiments.

Referring to FIG. 1, the plasma processing apparatus 10 may include a susceptor 100, a housing 200, a shower head 202, an exhaust port 210, and an exhaust pump 212.

The susceptor 100 may be arranged inside the housing 200. A wafer W may be disposed on a top surface of the susceptor 100, and the susceptor 100 may support and fix the wafer W. The susceptor 100 may be connected to an radio frequency (RF) power source to receive RF power from the RF power source. The susceptor 100 may include a susceptor support shaft 102, a susceptor body 110, an edge ring 120, and support pins 130.

The susceptor support shaft 102 arranged below the susceptor body 110 in the vertical direction may support the susceptor body 110. The susceptor support shaft 102 in a cylindrical shape may be arranged at the center of the housing 200.

The susceptor body 110 may be implemented in a cylindrical shape having a certain vertical thickness. The susceptor body 110 may include an inorganic material, such as quartz or aluminum nitride (AlN), or a metal, such as aluminum (Al). A central axis C of the susceptor body 110 may be the same as the central axis of the wafer W and the central axis of the housing 200. For example, the wafer W may be disposed on a top surface of the susceptor body 110 while being aligned with the susceptor body 110. A diameter D_{S} of the susceptor body 110 is greater than a diameter D_{W} of the wafer W.

A heater may be provided inside the susceptor body 110. The heater provided inside the susceptor body 110 may raise or lower the temperature of the wafer W. In addition, a lifting pin for lifting and lowering the wafer W while supporting the wafer W from below may be embedded in the susceptor body 110, and an electrostatic chuck for fixing and supporting the wafer W using an electrostatic force may be provided on the top surface of the susceptor body 110.

The edge ring 120 may be configured to form a uniform electric field in an upper region of the wafer W. The edge ring 120 may include, for example, aluminum oxide (Al₂O₃), silicon (Si), silicon oxide (SiO₂), quartz, silicon carbide (SiC), yttrium oxide (Y₂O₃), or a combination thereof. However, the material constituting the edge ring 120 is not limited to the above and may include other materials.

The edge ring 120 may be disposed above the susceptor body 110 in the vertical direction and may be implemented in a circular ring shape having a certain vertical thickness d. The central axis of the edge ring 120 may be aligned with the central axis C of the susceptor body 110. For example, the central axis of the edge ring 120 may be the same as the central axis C of the susceptor body 110.

An inner diameter of the edge ring 120 corresponds to the diameter D_{W} of the wafer W. As shown in FIG. 1, the inner diameter of the edge ring 120 may include a value obtained by adding the diameter D_{W} of the wafer W to twice an alignment interval Lₐ. The alignment interval Lₐ may be an interval between the wafer W and the edge ring 120 in the horizontal direction.

In one or more embodiments, the alignment interval Lₐ may be between about 0.5 mm and about 4 mm. For example, when the diameter D_{W} of the wafer W is 300 mm, the inner diameter of the edge ring 120 may be about 301 mm to about 308 mm. When the alignment interval Lₐ is set to 0.5 mm or more, plasma may more effectively penetrate between the wafer W and the edge ring 120. In addition, as the alignment interval Lₐ is set to 4 mm or less, an electric field may concentrate in the upper region of the wafer W without unnecessarily expanding in a radial direction.

According to one or more embodiments, as shown in FIG. 1, an outer diameter of the edge ring 120 may be equal to the diameter D_{S} of the susceptor body 110. In this case, a horizontal width Tₑ of the edge ring 120 may be equal to an edge width. The edge width is half of a value obtained by subtracting twice the sum of the diameter D_{W} of the wafer W and the alignment interval Lₐ from the diameter D_{S} of the susceptor body 110

$$( edge width = \frac{{D}_{S} - {D}_{W}}{2} - {L}_{a} ) .$$

According to one or more other embodiments, the outer diameter of the edge ring 120 is less than the diameter D_{S} of the susceptor body 110. In this case, the horizontal width Tₑ of the edge ring 120 may be less than the edge width (Tₑ<edge width). The horizontal width Tₑ of the edge ring 120 is half the difference between the outer diameter and the inner diameter of the edge ring 120.

The edge ring 120 may be spaced apart from the top surface of the susceptor body 110 in a vertically upward direction. A bottom surface of the edge ring 120 may be spaced apart from the top surface of the susceptor body 110 in the upward direction by a vertical thickness g of the support pin 130. The top surface of the edge ring 120 may be spaced apart from the top surface of the susceptor body 110 in the upward direction by a distance (g+d) obtained by adding the vertical thickness g of the support pin 130 to the vertical thickness d of the edge ring 120.

According to one or more embodiments, a level of the top surface of the edge ring 120 may be greater than the vertical level of the top surface of the wafer W. As shown in FIG. 1, the top surface of the wafer W may be spaced apart from the top surface of the susceptor body 110 in the vertically upward direction by a wafer width h_{w}. In this case, the sum (g+d) of the vertical thickness g of the support pin 130 and the vertical thickness d of the edge ring 120 may be greater than the wafer width h_{w}.

The support pin 130 may protrude from the top surface of the susceptor body 110 toward the bottom surface of the edge ring 120. A plurality of support pins 130 may protrude from the top surface of the susceptor body 110. The plurality of support pins 130 may support and fix the edge ring 120. In one or more embodiments, a top surface of each of the plurality of support pins 130 may be coupled and/or connected to the bottom surface of the edge ring 120, and the plurality of support pins 130 below the edge ring 120 may support the edge ring 120. For example, the top surface of each of the plurality of support pins 130 may contact the bottom surface of the edge ring 120. In one or more other embodiments, the plurality of support pins 130 may each include a clamp. In this case, the clamp included in each of the plurality of support pins 130 may be coupled and/or connected to the outer surface of the edge ring 120 to support and fix the edge ring 120. However, the above-mentioned example is only an example of how the support pins 130 support and fix the edge ring 120. The support pins 130 may support and fix the edge ring 120 in various ways.

According to one or more embodiments, the vertical thickness g of each of the plurality of support pins 130 may be 0.3 mm or more. For example, the bottom surface of the edge ring 120 may be spaced apart from the top surface of the susceptor body 110 by 0.3 mm or more toward the vertically upward direction. When the vertical thickness g of the support pin 130 is 0.3 mm or more, an exhaust space may be formed between the top surface of the susceptor body 110 and the bottom surface of the edge ring 120. Particles inside the housing 200 may be more efficiently exhausted through the exhaust space. The exhaust space formed between the top surface of the susceptor body 110 and the bottom surface of the edge ring 120 is described in detail with reference to the following drawings.

The housing 200 may define a plasma processing space. The housing 200 may be connected to a ground potential. The plasma processing space may refer to a space where plasma processing is performed on the wafer W. The plasma processing on the wafer W may include an etching process, a deposition process, a plasma cleaning process, or the like.

The shower head 202 may include a plurality of gas injection holes and may be connected to a gas supply source 204. The shower head 202 may receive the process gas from the gas supply source 204 and supply the process gas to the plasma processing space through the plurality of gas injection holes. In addition, the shower head 202 may be connected to the ground potential or may be connected to the RF power source to receive RF power from the RF power source.

Although FIG. 1 illustrates a capacitively-coupled plasma (CCP) chamber where plasma is formed in the plasma processing space based on the difference in potential applied to each of the susceptor 100, the shower head 202, and/or the housing 200, this is merely for convenience of description, and embodiments are not limited thereto. The plasma processing apparatus 10 may also be implemented as, for example, an inductively-coupled plasma (ICP) chamber or an electron cyclotron resonance (ECR) plasma chamber that is supplied with the RF power through a coil adjacent to the housing 200.

The exhaust port 210 may include a hole penetrating a portion of the housing 200. The exhaust port 210 may include a hole provided to discharge particles (e.g., ions, radicals, or by-products of the plasma processing) present inside the housing 200 to the outside of the housing 200.

The exhaust port 210 may be spaced apart from the central axis of the housing 200 (or the central axis C of the susceptor body 110) in the horizontal direction. In addition, the exhaust port 210 may be arranged at a lower vertical level than the wafer W and the susceptor body 110. In one or more embodiments, as shown in FIG. 1, the exhaust port 210 may be implemented as a hole penetrating a portion of the bottom surface of the housing 200.

The exhaust pump 212 may suck particles inside the housing 200 through the exhaust port 210. The exhaust pump 212 may be connected to the exhaust port 210 through an exhaust line. The exhaust pump 212 may be referred to as a vacuum pump.

When the exhaust port 210 and the exhaust pump 212 are arranged at the same position as the central axis C, the exhaust capacity distribution for the upper region of the exhaust pump 212 may be symmetrical. However, as shown in FIG. 1, as the exhaust port 210 and the exhaust pump 212 may be arranged at the position spaced apart from the central axis C in the horizontal direction, the exhaust capacity of the exhaust pump 212 for the upper region of the susceptor body 110 is distributed asymmetrically. The exhaust capacity of the exhaust pump 212 for the upper region of the susceptor body 110 may be a physical quantity indicating how well the exhaust pump 212 may suck particles present in the upper region of the susceptor body 110. The asymmetry of the exhaust capacity distribution of the exhaust pump 212 is described in detail with reference to the following drawings.

Although FIG. 1 shows one exhaust port 210 and one exhaust pump 212, various numbers of exhaust ports 210 and exhaust pumps 212 may be provided in the plasma processing apparatus 10. Although FIG. 1 shows that the exhaust port 210 and the exhaust pump 212 are spaced apart from the central axis C of the susceptor body 110 in the +X direction, this is only for convenience of description and embodiments are not limited thereto. The exhaust port 210 and the exhaust pump 212 may be spaced apart from the central axis C of the susceptor body 110 in the +X direction, the −X direction, the +Y direction, and/or the −Y direction. For example, the exhaust port 210 and the exhaust pump 212 may be spaced apart from the central axis C of the susceptor body 110 in the −X direction by 200 mm or may be spaced apart from the central axis C of the susceptor body 110 in the +Y direction by 350 mm.

Although FIG. 1 shows that the exhaust port 210 and the exhaust pump 212 are arranged in a partial region of the bottom surface of the housing 200 that is closer to the inner wall of the housing 200 than the central axis C of the susceptor body 110, this is merely an example. The position where the exhaust port 210 and the exhaust pump 212 are arranged may vary. For example, the exhaust port 210 may include a hole penetrating a portion of the sidewall of the housing 200.

As described above, the plasma processing apparatus 10 according to one or more embodiments may include the edge ring 120 having an outer diameter equal to or less than the diameter of the susceptor body 110, thereby preventing the edge ring 120 from colliding with another structure. For example, when the susceptor 100 is viewed in a vertically downward direction, the edge ring 120 may not protrude outside the susceptor body 110 and may not be covered by the susceptor body 110, thereby preventing the edge ring 120 from colliding with other structures even when the susceptor body 110 is driven in the Z direction.

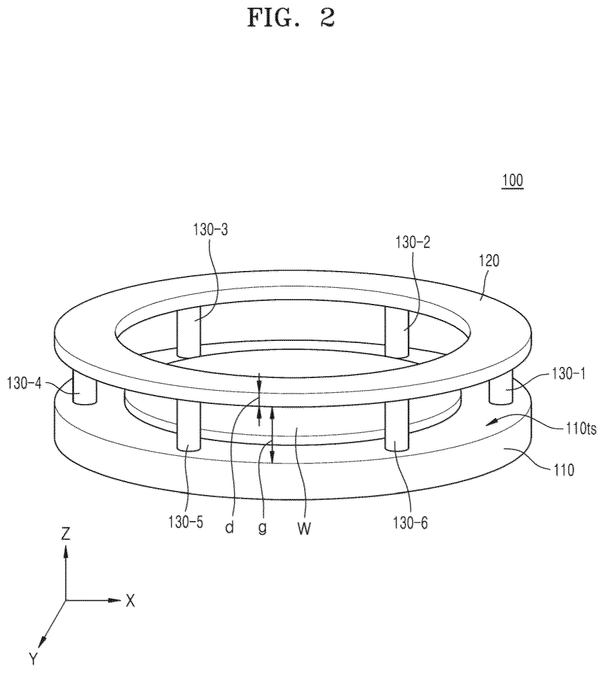

FIG. 2 is a perspective view of the susceptor 100 according to one or more embodiments. FIG. 2 is an enlarged view of the susceptor 1 in FIG. 1. FIG. 2 is described with reference to FIG. 1.

Referring to FIG. 2, the susceptor 100 may include the susceptor body 110, the edge ring 120, and a first support pin 130-1, a second support pin 130-2, a third support pin 130-3, a fourth support pin 130-4, a fifth support pin 130-5, and a sixth support pin 130-6.

The exhaust space may be formed between the top surface of the susceptor body 110, the bottom surface of the edge ring 120, and the first to sixth support pins 130-1, 130-2, 130-3, 130-4, 130-5, and 130-6. For example, particles inside the housing 200 may move toward the exhaust port 210 through the exhaust space surrounded by the top surface of the susceptor body 110, the bottom surface of the edge ring 120, and the first to sixth support pins 130-1, 130-2, 130-3, 130-4, 130-5, and 130-6.

For example, as shown in FIG. 2, when the first to sixth support pins 130-1, 130-2, 130-3, 130-4, 130-5, and 130-6 are formed to protrude from the top surface of the susceptor body 110, a total of six exhaust spaces may be formed. For example, the first exhaust space may include a space surrounded by the first support pin 130-1, the second support pin 130-2, the top surface of the susceptor body 110, and the bottom surface of the edge ring 120. In addition, the second exhaust space may include a space surrounded by the second support pin 130-2, the third support pin 130-3, the top surface of the susceptor body 110, and the bottom surface of the edge ring 120. Each of the third to sixth exhaust spaces may be formed based on the same principle.

As shown in FIGS. 1 and 2, when the first to sixth support pins 130-1, 130-2, 130-3, 130-4, 130-5, and 130-6 all have the same vertical thickness g, are spaced apart by the same radial distance with respect to the center of the susceptor body 110, and are radially spaced apart from each other by a constant angle (60°), the cross-sectional areas of the first to sixth exhaust spaces may all be the same. The cross-sectional area of any one exhaust space may be determined based on an interval between two support pins surrounding the one exhaust space, and a vertical thickness of the two support pins. For example, when the interval between the two support pins surrounding the one exhaust space is narrowed or the vertical thickness of the two support pins is reduced, the cross-sectional area of the one exhaust space may be reduced.

When the cross-sectional area of the exhaust space is reduced, the exhaust conductance of the exhaust space may be reduced. The exhaust conductance of the exhaust space is a physical quantity indicating how well gas can be exhausted through the exhaust space. As an example, the exhaust conductance of the exhaust space may be expressed as Equation 1 as follows:

$$C = 6.18 \frac{{A}^{2}}{DL} {( \frac{T}{M} )}^{1 / 2} \qquad [ Equation 1 ]$$

In Equation 1, C represents the exhaust conductance, A represents the cross-sectional area of the exhaust space, D represents the average diameter (e.g., horizontal width) of the exhaust space, and L represents the distance of the exhaust space. In addition, M represents the molecular weight of the particles to be exhausted, and T represents the temperature of the particles.

As seen from Equation 1, the exhaust conductance of the exhaust space may be proportional to the square A² of the cross-sectional area of the exhaust space. Therefore, by adjusting the cross-sectional area of any one exhaust space, the exhaust conductance of the one exhaust space may be adjusted.

According to one or more embodiments, the plasma processing apparatus 10 may control the conductance of the exhaust space by changing the vertical level of the bottom surface of the edge ring 120, the position of the support pins 130, the number of support pins 130, and/or the horizontal width of the support pins 130. As a result, although the exhaust capacity distribution of the exhaust pump 212 has an asymmetric distribution, the particles present above the susceptor body 110 may be uniformly exhausted in the radial direction.

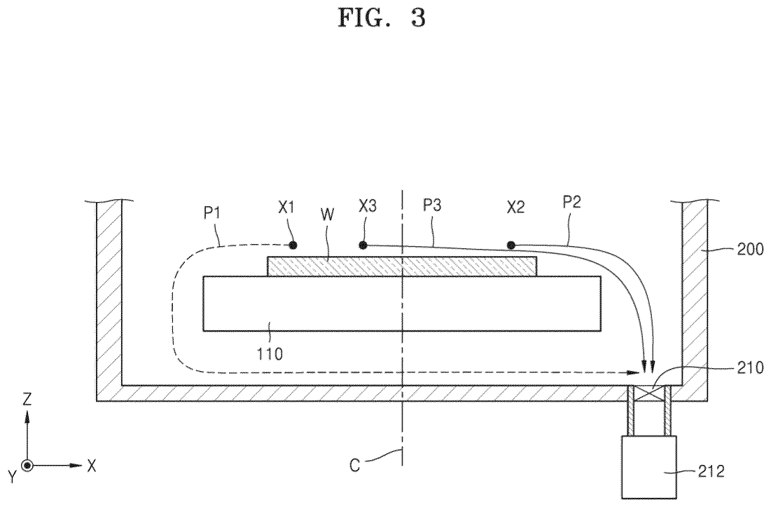

FIG. 3 is a cross-sectional view illustrating a particle movement path inside the plasma processing apparatus 10, according to one or more embodiments. FIG. 3 shows the housing 200, the susceptor body 110, the exhaust port 210, and the exhaust pump 212, omitting most components of the plasma processing apparatus 10 of FIG. 1, for convenience of description of the exhaust capacity distribution of the exhaust pump 212.

The particle movement path may refer to a movement path determined considering the flow of particles caused by suction (or pumping) of the exhaust pump 212, without considering the cross-sectional area of the exhaust space formed by the support pins 130 and the edge ring 120. For example, the particle movement path may refer to a movement path of each of the particles present above the susceptor body 110, assuming that the support pins 130 and the edge ring 120 are not arranged inside the housing 200.

According to one or more embodiments, the exhaust capacity distribution of the exhaust pump 212 for the upper region of the susceptor body 110 may be determined based on the particle movement path of each of the particles present in the upper region of the susceptor body 110. In addition, the particle movement path of each of the particles present in the upper region of the susceptor body 110 may be determined based on the relative position of the exhaust port 210 with respect to the susceptor body 110.

For example, when the exhaust port 210 is spaced apart from the central axis C of the susceptor body 110 in the horizontal direction, the particle movement path may be formed asymmetrically with respect to the central axis C of the susceptor body 110. For example, particles present at first point X1, in the upper region of the susceptor body 110, spaced apart from the central axis C of the susceptor body 110 in the −X direction by a first distance move along a first particle movement path P1 that moves in the −X direction and then moves in the vertically downward direction. Particles present at third point X3 spaced apart from the central axis C of the susceptor body 110 in the −X direction by a third distance less than the first distance may move along a third particle movement path P3 that moves in the +X direction and then moves in the vertically downward direction. For example, although the particles are located at points spaced apart from the central axis C of the susceptor body 110 in the same direction (e.g., −X direction), the particle movement paths (e.g., the first particle movement path P1 and the third particle movement path P3) may be formed in opposite directions depending on the distance from the central axis C of the susceptor body 110. The asymmetry of the particle movement path with respect to the central axis C of the susceptor body 110 may be determined based on the relative position of the exhaust port 210 with respect to the susceptor body 110.

The exhaust capacity distribution of the exhaust pump 212 for the upper region of the susceptor body 110 may be determined based on each of a plurality of particle movement paths. Each of the plurality of particle movement paths may refer to a path from each of a plurality of points above the susceptor body 110 to the exhaust port 210. As an example, the first particle movement path P1 may include a path from the first point X1 to the exhaust port 210, the second particle movement path P2 may include a path from the second point X2 to the exhaust port 210, and the third particle movement path P3 may include a path from the third point X3 to the exhaust port 210.

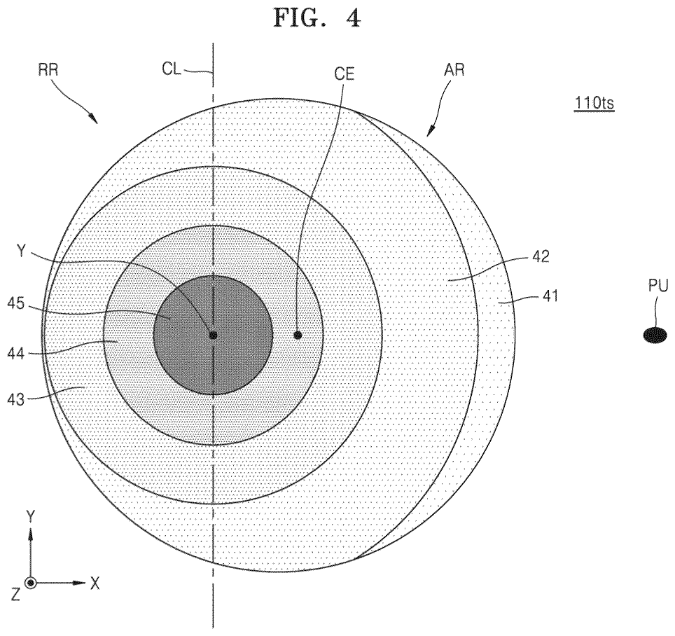

The exhaust capacity distribution of the exhaust pump 212 determined based on each of the plurality of particle movement paths is described in detail with reference to FIG. 4. Although it is described above that the particle movement path of each of the particles can be determined based on the relative position of the exhaust port 210 with respect to the susceptor body 110, and the type and flow rate of process gas introduced into the housing 200, this is merely an example of several factors that affect the determination of the particle movement path. Various factors, such as the width of the susceptor body 110, the type and flow rate of the process gas introduced into the housing 200, the overall size of the housing 200, the shape of the housing 200, and the type and output of the exhaust pump 212 may also affect the determination of the particle movement path.

FIG. 4 is a diagram illustrating the exhaust capacity distribution according to one or more embodiments. FIG. 4 is a top plan view of the susceptor body 110.

FIG. 4 is described with reference to FIG. 3. In addition, in the description with reference to FIG. 4, it is assumed that a pumping position PU is spaced apart from a center CE of a top surface 110ts of the susceptor body 110 in the +X direction. The pumping position PU may include a position where the exhaust port 210 is arranged when the susceptor body 110 is viewed from above.

Referring to FIG. 4, the top surface 110ts of the susceptor body 110 may be divided into a first pumping region 41, a second pumping region 42, a third pumping region 43, a fourth pumping region 44, and a fifth pumping region 45 according to the mass flux of particles present in the upper region of the susceptor body 110. The mass flux of particles in a specific region being high/low may directly correspond to the exhaust capacity of the exhaust pump 212 for the specific region being strong/weak. Although it is assumed that the top surface 110ts of the susceptor body 110 is divided into five pumping regions in the description with reference to FIG. 4, embodiments are not limited thereto, and the top surface 110ts of the susceptor body 110 may be divided into less than five pumping regions or six or more pumping regions.

According to one or more embodiments, the first pumping region 41 includes a region where the mass flux of particles is the highest. In addition, the fifth pumping region 45 includes a region where the mass flux of particles is the lowest. In addition, the mass flux of particles may be sequentially lowered in the order of the first pumping region 41, the second pumping region 42, the third pumping region 43, the fourth pumping region 44, and the fifth pumping region 45. In this case, particles arranged in a region adjacent to a center Y of the fifth pumping region 45 may flow very slowly.

According to one or more embodiments, the top surface 110ts of the susceptor body 110 may be divided into a pump-adjacent region AR and a pump-remote region RR based on a centerline CL. The centerline CL may include a straight line extending in a direction perpendicular to the direction (+X direction) from the center CE of the top surface 110ts of the susceptor body 110 toward the pumping position PU and passing through the center Y of the fifth pumping region 45.

The pump-adjacent region AR may include a region spaced apart from the centerline CL in the direction toward the pumping position PU (+X direction), among all regions of the top surface 110ts of the susceptor body 110. The particles in the pump-adjacent region AR may move along the particle movement path toward the +X direction on average. The pump-remote region RR may include a region spaced apart from the centerline CL in a direction (−X direction) opposite to the direction toward the pumping position PU, among all regions of the top surface 110ts of the susceptor body 110. The particles in the pump-remote region RR may move along the particle movement path toward the −X direction on average. For example, the average particle movement path of particles present in the pump-adjacent region AR may be in the opposite direction to the average particle movement path of particles present in the pump-remote region RR.

For example, the average particle movement path of particles present in the pump-adjacent region AR may be formed as a movement path where particles move toward the exhaust port 210 in the horizontal direction and then move in the vertically downward direction, such as the second particle movement path P2 and the third particle movement path P3 in FIG. 3. The average particle movement path of particles present in the pump-remote region RR may be formed as a movement path where particles move away from the exhaust port 210 in the horizontal direction and then move in the vertically downward direction, such as the first particle movement path P1 in FIG. 3.

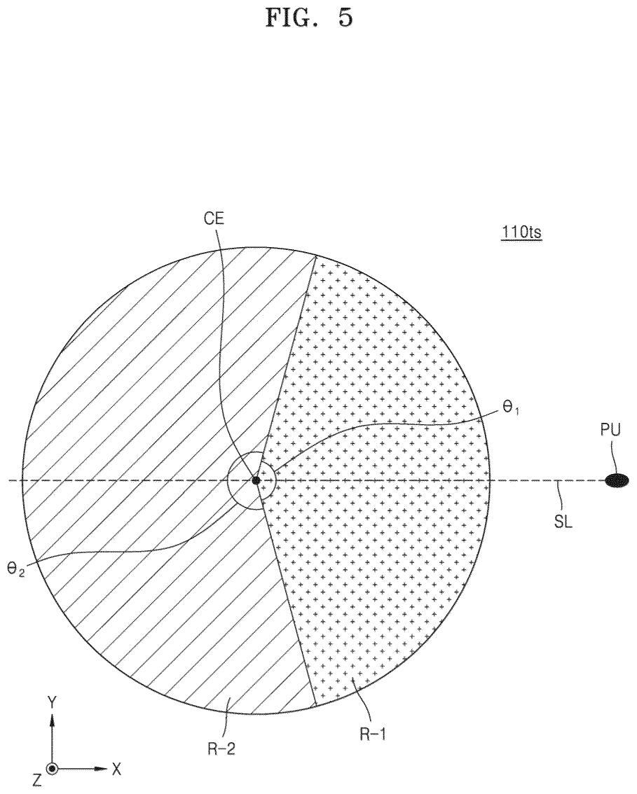

As described above with reference to FIG. 3, the position of the centerline CL may be determined based on the relative position of the exhaust port 210 with respect to the susceptor body 110 because the centerline CL is a straight line that distinguishes the direction of the average particle movement path of particles. As an example, when the pumping position PU is further away from the center CE of the top surface 110ts of the susceptor body 110 in the +X direction than shown in FIG. 4, the position of the centerline CL may be further away from the center CE of the top surface 110ts of the susceptor body 110 in the −X direction than shown in FIG. 4. As another example, when the pumping position PU is located closer to the center CE of the top surface 110ts of the susceptor body 110 than shown in FIG. 4, the position of the centerline CL may be located closer to the center CE of the top surface 110ts of the susceptor body 110 than shown in FIG. 5.

According to one or more embodiments, the exhaust capacity distribution of the exhaust pump 212 for the pump-adjacent region AR may be determined based on the distance between the exhaust port 210 and each of the plurality of particle movement paths formed from each of the plurality of points present in the pump-adjacent region AR. For example, as the particle movement path formed from a specific point present in the pump-adjacent region AR to the exhaust port 210 increases, the exhaust capacity of the exhaust pump 212 for the specific point may increase.

In addition, the exhaust capacity distribution of the exhaust pump 212 for the pump-remote region RR may also be determined based on the distance between the exhaust port 210 and each of the plurality of particle movement paths formed from each of the plurality of points present in the pump-remote region RR. For example, as the particle movement path formed from a specific point present in the pump-remote region RR to the exhaust port 210 increases, the exhaust capacity of the exhaust pump 212 for the specific point may increase.

As described above, the exhaust capacity distribution of the exhaust pump 212 for the upper region of the susceptor body 110 may be determined based on the plurality of particle movement paths and thus have an asymmetrical distribution shape with respect to the center CE of the top surface 110ts of the susceptor body 110.

In addition, as described above with reference to FIGS. 3 and 4, the exhaust capacity distribution of the exhaust pump 212 is a physical quantity calculated considering only the relative position of the exhaust pump 212 with respect to the susceptor body 110 without considering the conductance of the exhaust space formed between the top surface of the susceptor body 110 and the bottom surface of the edge ring 120. The plasma processing apparatus 10 may compensate for the asymmetric exhaust capacity distribution, as described above, by setting the exhaust conductance to be different for each region. A method of setting the exhaust conductance of the plasma processing apparatus 10 to be different for each region is described in detail with reference to the following drawings. First, a method of dividing the top surface 110ts of the susceptor body 110 into a plurality of regions based on the exhaust capacity distribution is described with reference to FIG. 5.

FIG. 5 is a diagram of a plurality of divided regions according to one or more embodiments.

Referring to FIG. 5, the top surface 110ts of the susceptor body 110 may include a first region R-1 and a second region R-2. The first and second regions R-1 and R-2 may be distinguished based on the exhaust capacity distribution of the exhaust pump 212 for the upper region of the susceptor body 110.

According to one or more embodiments, as shown in FIG. 5, the top surface 110ts of the susceptor body 110 may be divided into the first region R-1 and the second region R-2. The first region R-1 including a region adjacent to the pumping position PU may be referred to as a strong exhaust region. The second region R-2 including a region farther away from the pumping position PU than the first region R-1 may be referred to as a weak exhaust region.

The first region R-1 may include a fan-shaped region where the center CE of the top surface 110ts of the susceptor body 110 is the center of the fan and a first angle θ₁ is a central angle of the fan. The second region R-2 may include a fan-shaped region where the center CE of the top surface 110ts of the susceptor body 110 is the center of the fan and a second angle θ₂ is a central angle of the fan. The second angle θ₂ may be greater than the first angle θ₁. In addition, the first angle θ₁ may be, for example, about 300 to about 180°.

According to one or more embodiments, each of the first region R-1 and the second region R-2 may be implemented in a fan shape that is symmetric with respect to a line of symmetry SL. The line of symmetry SL is a straight line in the horizontal direction from the center CE of the top surface 110ts of the susceptor body 110 toward the pumping position PU. In one or more embodiments, as shown in FIG. 5, the second region R-2 may include a region in the entire region of the top surface 110ts of the susceptor body 110, excluding the first region R-1.

According to one or more embodiments, the first angle θ₁ may be determined based on the degree of asymmetry of the exhaust capacity of the exhaust pump 212. When the degree of asymmetry is relatively large, the first angle θ₁ may have a relatively large value. When the degree of asymmetry is relatively small, the first angle θ₁ may have a relatively small value. For example, the degree of asymmetry of the exhaust capacity of the exhaust pump 212 may correspond to the first angle θ₁. As an example, referring back to FIG. 4, the degree of asymmetry of the exhaust capacity of the exhaust pump 212 may be determined based on the position of the center Y of the fifth pumping region 45 (the region with the lowest exhaust capacity) in FIG. 4. For example, when the position of the center Y is far away from the center CE of the top surface 110ts of the susceptor body 110, the degree of asymmetry of the exhaust capacity may be relatively large and the first angle θ₁ may be relatively large. When the position of the center Y is very close to the center CE of the top surface 110ts of the susceptor body 110, the degree of asymmetry of the exhaust capacity may be relatively small and the first angle θ₁ may be relatively small.

As another example, referring back to FIG. 4, the degree of asymmetry of the exhaust capacity of the exhaust pump 212 may be determined based on the position of the centerline CL in FIG. 4. For example, when the position of the centerline CL is relatively far away from the center CE of the top surface 110ts of the susceptor body 110, the degree of asymmetry of the exhaust capacity may be relatively large and the first angle θ₁ may be relatively large. When the position of the centerline CL is very close to the center CE of the top surface 110ts of the susceptor body 110, the degree of asymmetry of the exhaust capacity may be relatively small and the first angle θ₁ may be relatively small.

The above-described example is merely examples for identifying the degree of asymmetry of the exhaust capacity. A method of identifying the degree of asymmetry of the exhaust capacity may be performed based on various methods.

As described above with reference to FIG. 5, the top surface 110ts of the susceptor body 110 may be divided into the first region R-1 that is a relatively strong exhaust region and the second region R-2 that is a relatively weak exhaust region, based on the exhaust capacity distribution of the exhaust pump 212. The exhaust conductance of the exhaust space formed in the first region R-1 may be different from the exhaust conductance of the exhaust space formed in the second region R-2. For example, as the cross-sectional areas of the exhaust spaces formed in the first region R-1 and the second region R-2 are formed to be different from each other, the conductance of the exhaust space formed in the first region R-1 may be set to be different from the conductance of the exhaust space formed in the second region R-2.

According to one or more embodiments, among a plurality of regions (e.g., the first region R-1 and the second region R-2), a cross-sectional area of an exhaust space formed in a region with a relatively strong exhaust capacity (e.g., the first region R-1) may be less than a cross-sectional area of an exhaust space formed in a region with a relatively weak exhaust capacity (e.g., the second region R-2). The cross-sectional area of the exhaust space formed in each of the plurality of regions may be determined based on the number of region support pins per unit area arranged in each of the plurality of regions, the horizontal width of the region support pins, and the vertical thickness of the region support pins. The region support pin may be a support pin arranged in a specific region. For example, a first region support pin may be a support pin arranged in the first region R-1, and a second region support pin may be a support pin arranged in the second region R-2.

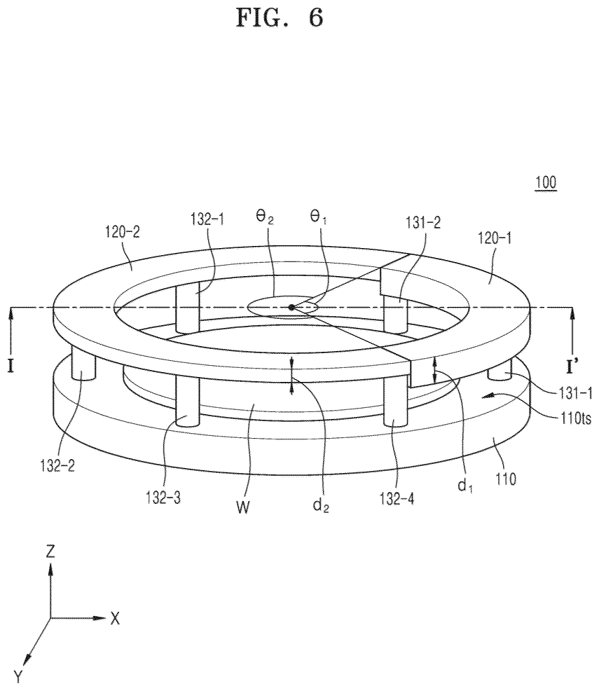

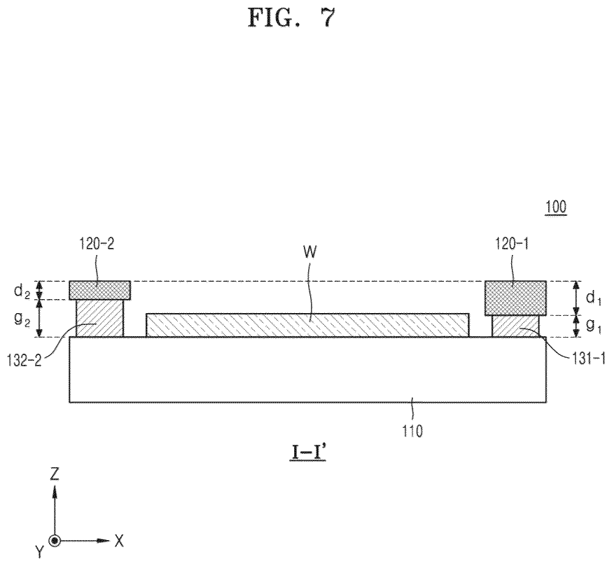

In the following description with reference to FIGS. 6 and 7, a plurality of first region support pins and a plurality of second region support pins arranged in the first region R-1 and the second region R-2, respectively, have different vertical thicknesses from each other. Thus, the exhaust conductance of the exhaust space formed in each of the first region R-1 and the second region R-2 may be set to be different.

FIG. 6 is a perspective view of the susceptor 100 according to one or more embodiments. FIG. 7 is a cross-sectional view of the susceptor 100 taken along line I-I′ in FIG. 6.

Referring to FIGS. 6 and 7, a plurality of first region support pins 131-1 and 131-2 may be arranged in the first region R-1, and a plurality of second region support pins 132-1, 132-2, 132-3, and 132-4 may be arranged in the second region R-2. The edge ring 120 may include a first region ring 120-1 disposed above the first region R-1 and a second region ring 120-2 disposed above the second region R-2. A vertical level of a top surface of the first region ring 120-1 may be the same as a vertical level of a top surface of the second region ring 120-2.

The plurality of first region support pins 131-1 and 131-2 may support the first region ring 120-1, and the plurality of second region support pins 132-1, 132-2, 132-3, and 132-4 may support the second region ring 120-2.

According to one or more embodiments, a first vertical thickness g₁ of each of the plurality of first region support pins 131-1 and 131-2 may be relatively less than a second vertical thickness g₂ of each of the plurality of second region support pins 132-1, 132-2, 132-3, and 132-4. For example, since the top surface of the first region ring 120-1 and the top surface of the second region ring 120-2 are arranged at the same vertical level, a vertical thickness d1 of the first region ring 120-1 may be greater than a vertical thickness d2 of the second region ring 120-2, and a bottom surface of the first region ring 120-1 may be arranged at a lower level lower than a vertical level of a bottom surface of the second region ring 120-2.

The the first vertical thickness g₁ of the first region support pin 131-1 being less/greater than the second vertical thickness g₂ of the second region support pin 132-2 may directly correspond to the vertical level of the bottom surface of the first region ring 120-1 being less/greater than the vertical level of the bottom surface of the second region ring 120-2.

In the first region R-1, any one exhaust space surrounded by the bottom surface of the first region ring 120-1, the top surface 110ts of the susceptor body 110, and the plurality of first region support pins 131-1 and 131-2 may have a height equal to the first vertical thickness g₁ in the vertical direction. In the second region R-2, any one exhaust space surrounded by the bottom surface of the second region ring 120-2, the top surface 110ts of the susceptor body 110, and the plurality of second region support pins 132-1, 132-2, 132-3, and 132-4 may have a height equal to the second vertical thickness g₂ greater than the first vertical thickness g₁ in the vertical direction.

Consequently, the cross-sectional area of any one exhaust space formed in the second region R-2 may be greater than the cross-sectional area of any one exhaust space formed in the first region R-1. Accordingly, the exhaust conductance of the exhaust space formed in the second region R-2 may be greater than the exhaust conductance of the exhaust space formed in the first region R-1. Due to the difference in exhaust conductance between the exhaust space formed in the first region R-1 and the exhaust space formed in the second region R-2, the asymmetric exhaust capacity distribution as described with reference to FIG. 3 and FIG. 4 may be compensated.

According to one or more embodiments, based on the difference in exhaust capacity of the exhaust pump 212 between the first region R-1 and the second region R-2, the difference between the vertical level of the bottom surface of the first region ring 120-1 and the vertical level of the bottom surface of the second region ring 120-2 may be determined.

For example, when the difference in exhaust capacity of the exhaust pump 212 between the first region R-1 and the second region R-2 is relatively small, the difference between the vertical level of the bottom surface of the first region ring 120-1 and the vertical level of the bottom surface of the second region ring 120-2 may be relatively small. When the difference in exhaust capacity of the exhaust pump 212 between the first region R-1 and the second region R-2 is relatively large, the difference between the vertical level of the bottom surface of the first region ring 120-1 and the vertical level of the bottom surface of the second region ring 120-2 may be relatively large.

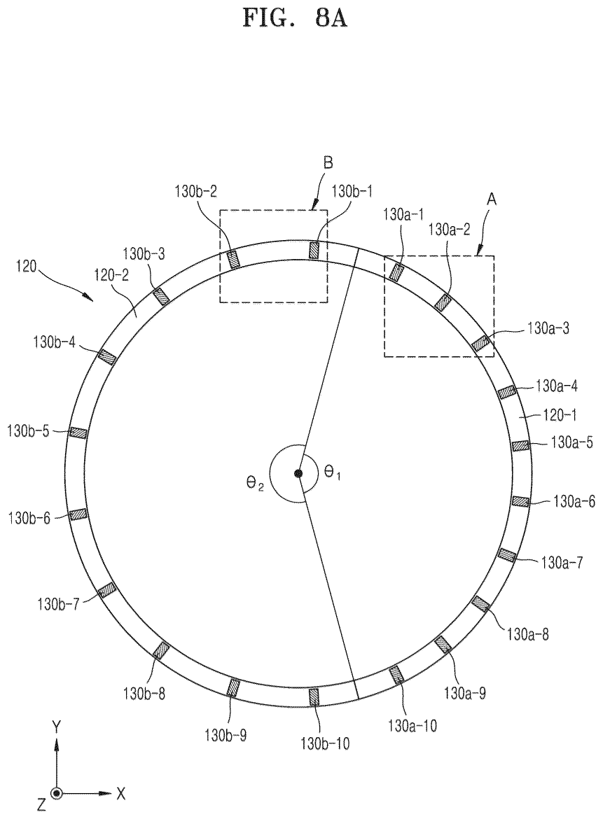

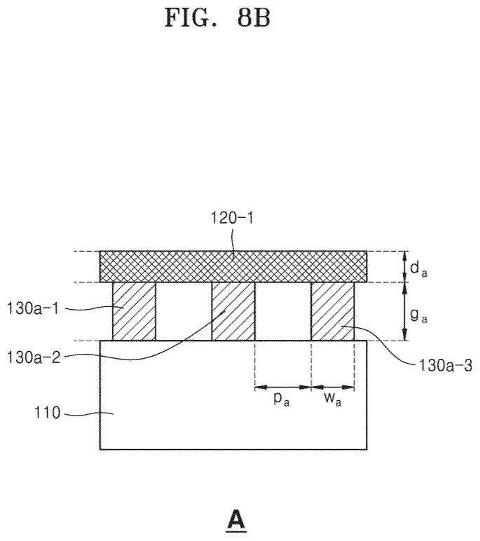

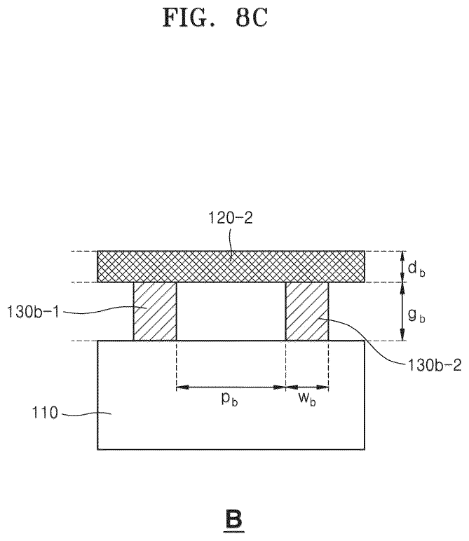

In the following description with reference to FIGS. 8A to 8C, the exhaust conductance of the exhaust space formed in each of the first region R-1 and the second region R-2 may be set to be different as the horizontal interval of support pins arranged in the first region R-1 is implemented to have a different value from that of support pins arranged in the second region R-2.

FIGS. 8A to 8C are cross-sectional views of an edge ring and support pins, according to one or more embodiments. FIG. 8B is an enlarged cross-sectional view of portion “A” in FIG. 8A, and FIG. 8C is an enlarged cross-sectional view of portion “B” in FIG. 8A.

FIG. 8A is a cross-sectional view of the edge ring 120 and the plurality of support pins 130 disposed on the bottom surface of the edge ring 120, as viewed from a top plan view. Referring to FIG. 8A, a plurality of first region support pins 130a-1, 130a-2, . . . , 130a-10 and the first region ring 120-1 may be arranged in the first region R-1. In addition, a plurality of second region support pins 130b-1, 130b-2, . . . , 130b-10 and the second region ring 120-2 may be arranged in the second region R-2.

In the first region R-1, the first region ring 120-1 may be disposed on the plurality of first region support pins 130a-1, 130a-2, . . . , and 130a-10, and the plurality of first region support pins 130a-1, 130a-2, . . . , and 130a-10 may fix and support the first region ring 120-1. In the second region R-2, the second region ring 120-2 may be disposed on the plurality of second region support pins 130b-1, 130b-2, . . . , and 130b-10, and the plurality of second region support pins 130b-1, 130b-2, . . . , 130b-10 may fix and support the second region ring 120-2.

As shown in FIGS. 8B and 8C, a first interval pₐ between each of the plurality of first region support pins 130a-1, 130a-2, . . . , 130a-10 may be less than a second interval p_{b} between each of the plurality of second region support pins 130b-1, 130b-2, . . . , 130b-10. In the description with reference to FIGS. 8A to 8C, the first vertical thickness gₐ of each of the plurality of first region support pins 130a-1, 130a-2, . . . , and 130a-10 may be equal to the second vertical thickness g_{b} of each of the plurality of second region support pins 130b-1, 130b-2, . . . , and 130b-10 (gₐ=g_{b}). For example, the bottom surface of the first region ring 120-1 and the bottom surface of the second region ring 120-2 may be arranged at the same vertical level.

According to one or more embodiments, a number of support pins per second unit area of the second region R-2 may be less than a number of support pins per first unit area of the first region R-1. In this case, the first interval pₐ may be less than the second interval p_{b}. For example, as shown in FIG. 8A, the number of first region support pins 130a-1, 130a-2, . . . , and 130a-10 may be 10, and the number of second region support pins 130b-1, 130b-2, . . . 130b-10 may also be 10. Since the area of the second region R-2 is greater than the area of the first region R-1, the number of support pins per first unit area may be greater than the number of support pins per second unit area.

Herein, the number of support pins per unit area of a specific region may be a value obtained by dividing the number of region support pins arranged in a specific region by the area of the specific region. As an example, when the area of the first region R-1 is 20 cm² and the number of first region support pins 130a-1, 130a-2, . . . , and 130a-10 is 10, the number of support pins per first unit area of the first region R-1 may be 0.5/cm².

However, the number of first region support pins 130a-1, 130a-2, . . . , and 130a-10 and the number of second region support pins 130b-1, 130b-2, . . . , and 130b-10 shown in FIG. 8A are merely examples. The numbers thereof may be implemented as 10 or more or less than 10.

According to one or more other embodiments, the second horizontal width w_{b} of each of the plurality of second region support pins 130b-1, 130b-2, . . . , 130b-10 arranged in the second region R-2 may be less than first horizontal width wₐ of each of the plurality of first region support pins 130a-1, 130a-2, . . . , 130a-10 arranged in the first region R-1. In this case, the first interval pₐ may be less than the second interval p_{b}. For example, even when the number of support pins per first unit area of the first region R-1 is is equal to the number of support pins per second unit area of the second region R-2, the first interval pₐ may be set to be less than the second interval p_{b} by implementing the first horizontal width wₐ to be greater than the second horizontal width w_{b}.

As described above, each of the first interval pₐ and the second interval p_{b} may be adjusted/changed by adjusting/changing each of the number of support pins per first unit area, the number of support pins per second unit area, the first horizontal width wₐ, and the second horizontal width w_{b}. Accordingly, the cross-sectional area of the exhaust space formed in each of the first region R-1 and the second region R-2 may be adjusted by adjusting/changing each of the first interval pₐ and the second interval p_{b}.

For example, as shown in FIG. 8B, the cross-sectional area of any one exhaust space formed in the first region R-1 may include a value (pₐ*gₐ) obtained by multiplying the first interval pₐ by the first vertical thickness gₐ. As shown in FIG. 8C, the cross-sectional area of any one exhaust space formed in the second region R-2 may include a value (p_{b}*g_{b}) obtained by multiplying the second interval p_{b} by the second vertical thickness g_{b}. As the first interval pₐ is less than the second interval p_{b}, the cross-sectional area of the exhaust space formed in the first region R-1 may be less than the cross-sectional areas of the exhaust space formed in the second region R-2. Accordingly, the exhaust conductance of the exhaust space formed in the first region R-1 may be less than that of the exhaust space formed in the second region R-2. Due to the difference in the exhaust conductance between the exhaust space formed in the first region R-1 and the exhaust space formed in the second region R-2, the asymmetric exhaust capacity distribution as described with reference to FIGS. 3 and 4 may be compensated.

According to one or more embodiments, based on a difference between the exhaust capacity of the exhaust pump 212 for the first region R-1 and the exhaust capacity of the exhaust pump 212 for the second region R-2, the difference between the number of support pins per first unit area of the first region R-1 and the number of support pins per second unit area of the second region R-2 may be determined.

For example, when the difference between the exhaust capacity for the first region R-1 and the exhaust capacity for the second region R-2 is relatively small, the difference between the number of support pins per first unit area of the first region R-1 and the number of support pins per second unit area of the second region R-2 may be relatively small. When the difference between the exhaust capacity for the first region R-1 and the exhaust capacity for the second region R-2 is relatively large, the difference between the number of support pins per first unit area of the first region R-1 and the number of support pins per second unit area of the second region R-2 may be relatively large.

According to one or more other embodiments, a difference between the first horizontal width wₐ and the second horizontal width w_{b} may be determined based on the difference between the exhaust capacity of the exhaust pump 212 for the first region R-1 and the exhaust capacity of the exhaust pump 212 for the second region R-2. For example, when the difference between the exhaust capacity for the first region R-1 and the exhaust capacity for the second region R-2 is relatively small, the difference between the first horizontal width wₐ and the second horizontal width w_{b} may be small. When the difference between the exhaust capacity for the first region R-1 and the exhaust capacity for the second region R-2 is relatively large, the difference between the first horizontal width wₐ and the second horizontal width w_{b} may be relatively large.

In the above description with reference to FIGS. 6 and 7, the exhaust conductance of the exhaust space formed in the first region R-1 may be different from that of the exhaust space formed in the second region R-2 since the vertical level of the bottom surface of the first region ring 120-1 is implemented to be different from that of the bottom surface of the second region ring 120-2. In the description with reference to FIGS. 8A to 8C, the exhaust conductance of the exhaust space formed in the first region R-1 may be different from that of the exhaust space formed in the second region R-2 by implementing the first interval pₐ to be different from the second interval p_{b}. For example, in the above description, various methods of adjusting the exhaust conductance are separately described for convenience of description, but the methods may be implemented in combination.

As an example, the number of support pins per first unit area of the first region R-1 may be greater than the number of support pins per second unit area of the second region R-2, and the vertical level of the bottom surface of the first region ring 120-1 may be less than the vertical level of the bottom surface of the second region ring 120-2. As another example, the first horizontal width wₐ of the first region R-1 may be greater than the second horizontal width w_{b} of the second region R-2, and the vertical level of the bottom surface of the first region ring 120-1 may be less than the vertical level of the bottom surface of the second region ring 120-2. However, embodiments are not limited to the above-described examples. The exhaust conductance of the exhaust space formed in each region may be adjusted based on more various methods.

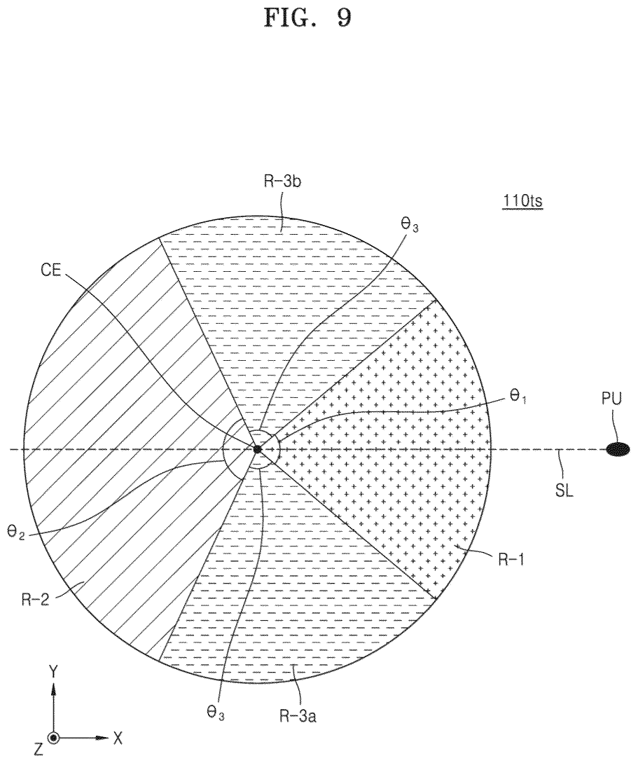

In the following description with reference to FIGS. 9 to 12D, one or more embodiments where the top surface 110ts of the susceptor body 110 is divided into a greater number of regions is described.

FIG. 9 is a diagram of a plurality of divided regions according to one or more embodiments.

Referring to FIG. 9, the top surface 110ts of the susceptor body 110 may include a plurality of regions R-1, R-2, R-3a, and R-3b. The plurality of regions R-1, R-2, R-3a, and R-3b may be distinguished based on the exhaust capacity distribution of the exhaust pump 212 for the upper region of the susceptor body 110.

As described above with reference to FIG. 5, the first region R-1, which is a region adjacent to relatively near the pumping position PU, may be referred to as a strong exhaust region. In addition, the second region R-2, which is a region relatively far away from the pumping position PU, may be referred to as a weak exhaust region. Each of the first region R-1 and the second region R-2 may include a fan-shaped region where the center CE of the top surface 110ts of the susceptor body 110 is the center of the fan, and the first angle θ₁ and the second angle θ₂ are the central angles of the fan. The second angle θ₂ may be greater than the first angle θ₁. In addition, each of the first region R-1 and the second region R-2 may be implemented in a fan shape that is symmetric with respect to the line of symmetry SL.

According to one or more embodiments, the top surface 110ts of the susceptor body 110 may include the plurality of third regions R-3a and R-3b between the first region R-1 and the second region R-2. Each of the plurality of third regions R-3a and R-3b may be referred to as an intermediate exhaust region. For example, the exhaust capacity of the exhaust pump 212 for each of the plurality of third regions R-3a and R-3b may be less than that of the exhaust pump 212 for the first region R-1 and may be greater than an exhaust capacity of the exhaust pump 212 for the second region R-2.

Each of the plurality of third regions R-3a and R-3b may have a fan-shaped region where the center CE of the top surface 110ts of the susceptor body 110 is the center of the fan and the third angle θ₃ is a central angle of the fan. As shown in FIG. 9, the third angle θ₃ is half a value obtained by subtracting the first angle θ₁ and second angle θ₂ from 360 degrees

$$( {θ}_{3} = \frac{360 ° - {θ}_{1} - {θ}_{2}}{2} ) .$$

According to one or more embodiments, the third angle θ₃ may be less than the first angle θ₁ and second angle θ₂ (θ₃<θ₁, θ₃<θ₂). In addition, twice the third angle θ₃ may be greater than the first angle θ₁ and may be equal to and less than the second angle θ₂. (2θ₃>θ₁, 2θ₃≤θ₂). However, the size relationship between the first angle θ₁, the second angle θ₂, and the third angle θ₃ is merely an example. The size relationship between the first angle θ₁, the second angle θ₂, and the third angle θ₃ may be set in various ways depending on the degree of asymmetry of the exhaust capacity distribution.

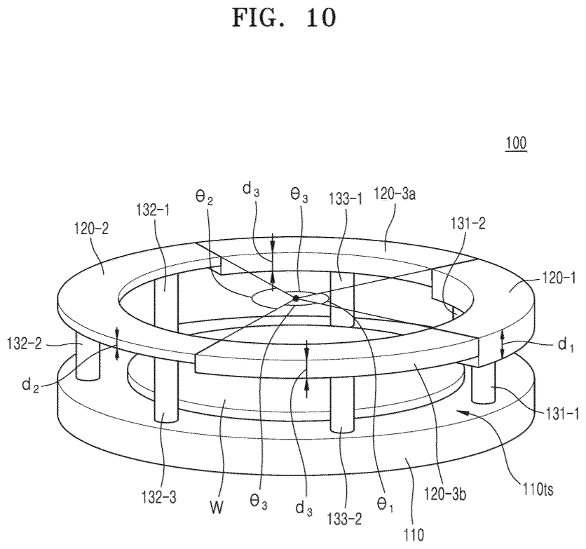

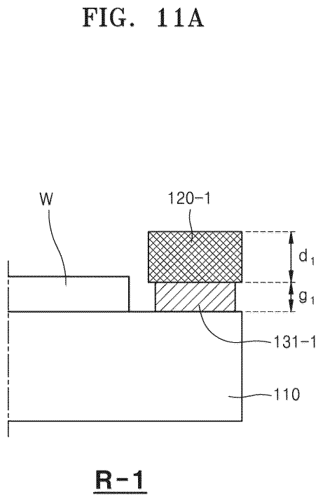

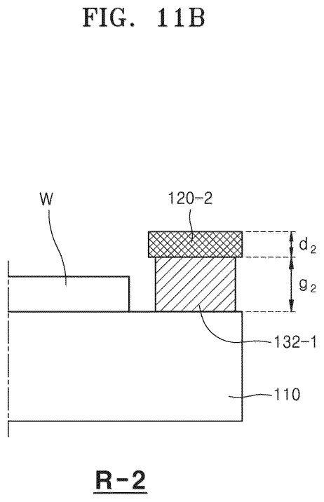

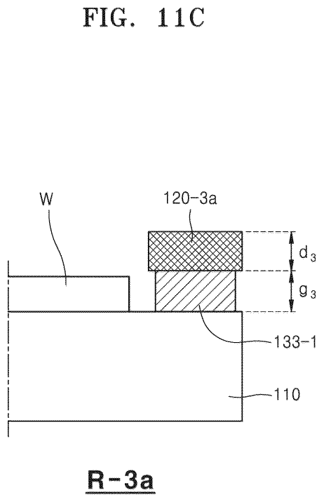

As shown in FIG. 9, as the plurality of third regions R-3a and R-3b are arranged between the first region R-1 and the second region R-2, the susceptor 100 according to one or more embodiments may achieve the effect of more accurately compensating for the asymmetry of the exhaust capacity distribution. For example, the susceptor 100 may set the cross-sectional areas of the exhaust spaces formed in the first region R-1, the second region R-2, and the plurality of third regions R-3a and R-3b to be different from each other. Accordingly, the conductance of the exhaust space formed in each of the first region R-1, the second region R-2, and the plurality of third regions R-3a and R-3b may be set to be different. In the following description with reference to FIGS. 10 to 11C, one or more embodiments in which the conductance of the exhaust space is set to be different through a method of setting the vertical level of the bottom surface of the region ring disposed above each of the first region R-1, the second region R-2, and the plurality of third regions R-3a and R-3b to be different is described.

FIG. 10 is a perspective view of the susceptor according to one or more embodiments. FIGS. 11A to 11C are cross-sectional views of the edge ring and the support pins, according to one or more embodiments.

Referring to FIGS. 10 to 11C, the plurality of first region support pins 131-1 and 131-2 may be arranged in the first region R-1, the plurality of second region support pins 132-1 and 132-2 may be arranged in the second region R-2, a third-1 region support pin 133-1 may be arranged in a third-1 region R-3a, and a third-2 region support pin 133-2 may be arranged at a third-2 region R-3b. The edge ring 120 may include a first region ring 120-1 disposed above the first region R-1, a second region ring 120-2 disposed above the second region R-2, a third-1 region ring 120-3a disposed above the third-1 region R-3a, and a third-2 region ring 120-3b disposed above the third-2 region R-3b. The vertical level of the top surface of the first region ring 120-1, the vertical level of the top surface of the second region ring 120-2, the vertical level of the top surface of the third-1 region ring 120-3a, and the vertical level of the top surface of the third-2 region ring 120-3b may be the same (d₁+g₁=d₂+g₂=d₃+g₃).

According to one or more embodiments, the first vertical thickness g₁ of the plurality of first region support pins 131-1 and 131-2, the third vertical thickness g₃ of the plurality of third region support pins 133-1 and 133-2, and the second vertical thickness g₂ of the plurality of second region support pins 132-1, 132-2, and 132-3 may sequentially increase (g₁<g₃<g₂). For example, since the top surface of the first region ring 120-1, the top surface of the second region ring 120-2, the top surface of the third-1 region ring 120-3a, and the top surface of the third-2 region ring 120-3b are arranged at the same vertical level, the vertical thickness d₁ of the first region ring 120-1, the vertical thickness d₃ of the third-1 region ring 120-3a and third-2 region ring 120-3b, and the vertical thickness d₂ of the second region ring 120-2 may sequentially decrease (d₁>d₃>d₂).

As shown in FIG. 11A, in the first region R-1, any one exhaust space surrounded by the bottom surface of the first region ring 120-1, the top surface 110ts of the susceptor body 110, and the plurality of first region support pins 131-1 and 131-2 may have a height equal to the first vertical thickness g₁ in the vertical direction.

As shown in FIG. 11B, in the second region R-2, any one exhaust space surrounded by the bottom surface of the second region ring 120-2, the top surface 110ts of the susceptor body 110, and the plurality of second region support pins 132-1, 132-2, 132-3, and 132-4 may have a height equal to the second vertical thickness g₂ greater than the first vertical thickness g₁ in the vertical direction.

In addition, as shown in FIG. 11C, in the third-1 region R-3a, any one exhaust space surrounded by the bottom surface of the third region ring 120-3, the top surface 110ts of the susceptor body 110, and the third-1 region support pin 133-1 may have a height equal to the third vertical thickness g₃ that is less than the second vertical thickness g₂ and greater than the first vertical thickness g₁ in the vertical direction.

Consequently, the cross-sectional area of any one exhaust space formed in each of the plurality of third regions R-3a and R-3b may be greater than the cross-sectional areas of any one exhaust space formed in the first region R-1 and may be less than the cross-section area of any one exhaust space formed in the second region R-2. Accordingly, the exhaust conductance of the exhaust space formed in each of the plurality of third regions R-3a and R-3b may be greater than that of the exhaust space formed in the first region R-1 and may be less than that of the exhaust space formed in the second region R-2. Due to the difference in the exhaust conductance between the exhaust space formed in the first region R-1, the exhaust space formed in the second region R-2, and the exhaust space formed in each of the plurality of third regions R-3a and R-3b, the asymmetric exhaust capacity distribution of the exhaust pump 212 may be precisely compensated.

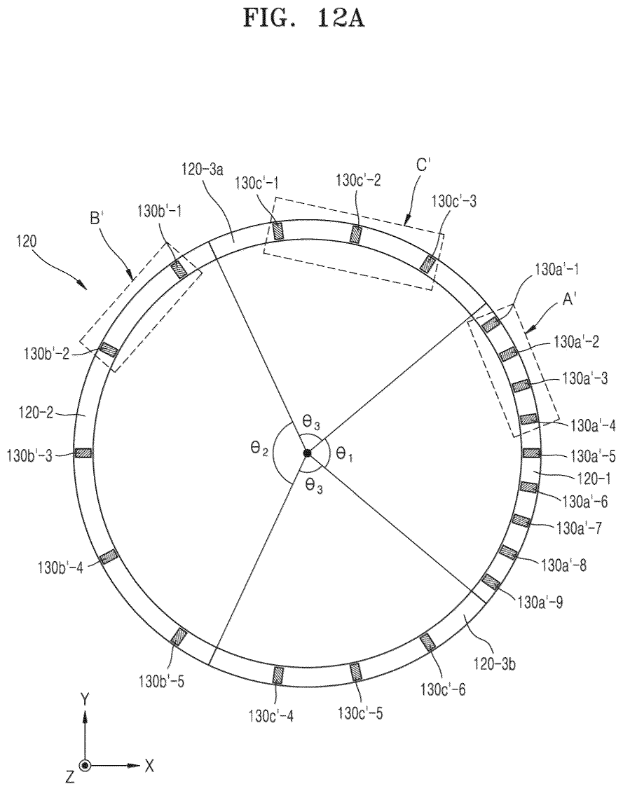

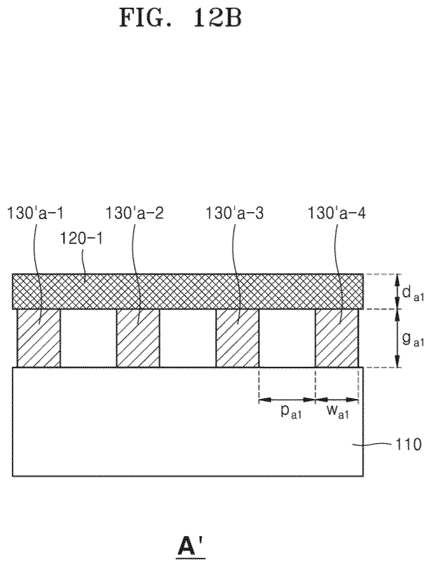

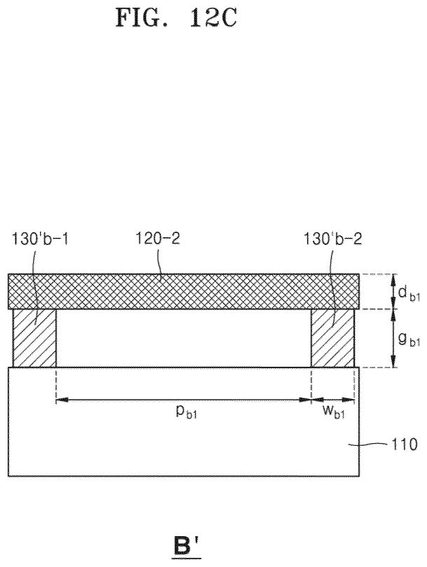

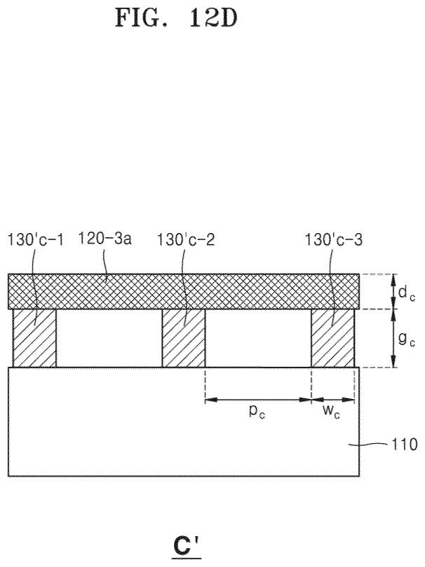

In the following description with reference to FIG. 12A to FIG. 12D, the exhaust conductance of the exhaust space formed in each of the first region R-1, the second region R-2, and the plurality of third regions R-3a and R-3b may be set to be different, as the horizontal intervals of the support pins arranged in the second region R-1 and the plurality of second regions R-3a are implemented to have different values.

FIGS. 12A to 12D are cross-sectional views of the edge ring and support pins, according to one or more embodiments. FIG. 12B is an enlarged cross-sectional view of portion “A′” in FIG. 12A, FIG. 12C is an enlarged cross-sectional view of portion “B′” in FIG. 12A, and FIG. 12D is an enlarged cross-sectional view of portion “C′” in FIG. 12A.

FIG. 12A is a cross-sectional view of the edge ring 120 and the plurality of support pins 130 disposed on the bottom surface of the edge ring 120, as viewed from a top plan view. Referring to FIG. 12A, a plurality of first region support pins 130a′-1, 130a′-2, . . . , 130a′-9 and the first region ring 120-1 may be arranged in the first region R-1, and a plurality of second region support pins 130b′-1, 130b′-2, . . . , 130b′-5 and the second region ring 120-2 may be arranged in the second region R-2. In addition, a plurality of third-1 region support pins 130c′-1, 130c′-2, and 130c′-3 and the third-1 region ring 120-3a may be arranged in the third-1 region R-3a, and a plurality of third-2 region support pins 130c′-4, 130c′-5, and 130c′-6 and the third-2 region ring 120-3b may be arranged in the third-2 region R-3b.

As shown in FIG. 12B, FIG. 12C, and FIG. 12D, a first interval pₐ₁ between each of the plurality of first region support pins 130a′-1, 130a′-2, . . . , 130a′-9, a third interval p_{c} between each of the third-1 region support pins 130c′-1, 130c′-2, and 130c′-3 and the plurality of third-2 region support pins 130c′-4, 130c′-5, and 130c′-6, and a second interval p_{b1} between each of the plurality of second region support pins 130b′-1, 130b′-2, . . . , and 130b′-5 may sequentially increase (pₐ₁<p_{c}<p_{b1}).

According to one or more embodiments, the number of support pins per first unit area of the first region R-1, the number of support pins per third unit area of the third-1 region R-3a and the third-2 region R-3b, and the number of support pins per second unit area of the second region R-2 may sequentially decrease. For example, the number of support pins per first unit area may be greatest, the number of support pins per second unit area may be least, and the number of support pins per third unit area may be less than the number of support pins per first unit area and greater than the number of support pins per second unit area. In this case, the first interval pₐ₁, the third interval p_{c}, and the second interval p_{b} may sequentially increase (pₐ₁<p_{c}<p_{b1}). For example, as shown in FIG. 12A, the number of first region support pins 130a′-1, 130a′-2, . . . , and 130a′-9 may be 9, the number of second region support pins (30b′-1, 130b′-2, . . . , and 130b′-5 may be 5, and the number of third region support pins 130c′-1, 130c′-2, 130c′-3, 130c′-4, 130c′-5, and 130c′-6 may be 6.

However, the number of first region support pins 130a′-1, 130a′-2, . . . , and 130a′-9, the number of second region support pins 130b′-1, 130b′-2, and 130b′-5, and the number of third region support pins 130c′-1, 130c′-2, 130c′-3, 130c′-4, 130c′-5, and 130c′-6 shown in FIG. 12A are merely examples. The numbers thereof may be implemented in various ways.

According to one or more other embodiments, the first horizontal width wₐ₁ of each of the plurality of first region support pins 130a′-1, 130a′-2, . . . , 130a′-9, the third horizontal width w_{c} of each of the plurality of third region support pins 130c′-1, 130c′-2, 130c′-3, 130c′-4, 130c′-5, and 130c′-6, and the second horizontal width w_{b1} of each of the plurality of second region support pins 130b′-1, 130b′-2, . . . , and 130b′-5 may sequentially decrease (wₐ₁>w_{c}>w_{b1}). In this case, the first interval pₐ₁, the third interval p_{c}, and the second interval p_{b1} may sequentially increase (pₐ₁<p_{c}<p_{b1}). For example, the first interval pₐ₁, the third interval p_{c}, and the second interval p_{b1} may be sequentially increased by sequentially decreasing the first horizontal width wₐ₁, the third horizontal width w_{c}, and the secondary horizontal width w_{b1} (pₐ₁<p_{c}<p_{b1}) even when the number of support pins per first unit area of the first region R-1, the number of support pins per third unit area of the third-1 region R-3a and the third-2 region R-3b, and the number of support pins per second unit area of the second region R-2 are the same.

As described above, each of the first interval pₐ₁, the second interval p_{b1}, and the third interval p_{c} may be adjusted/changed by adjusting/changing each of the number of support pins per first unit area, the number of support pins per second unit area, the number of third support pins per third unit area, the first horizontal width wₐ₁, the second horizontal width w_{b1}, and the third horizontal width w_{c}. Accordingly, the cross-sectional area of the exhaust space formed in each of the first region R-1, the second region R-2, and the plurality of third regions R-3a and R-3b may be adjusted/changed.

For example, as shown in FIG. 12B, the cross-sectional area of any one exhaust space formed in the first region R-1 may include a value (pₐ₁*gₐ₁) obtained by multiplying the first interval pₐ₁ by the first vertical thickness gₐ₁. As shown in FIG. 12C, the cross-sectional area of any one exhaust space formed in the second region R-2 may include a value (p_{b1}*g_{b1}) obtained by multiplying the second interval p_{b1} by the second vertical thickness g_{b1}. As shown in FIG. 12D, the cross-sectional area of any one exhaust space formed in each of the plurality of third regions R-3a and R-3b may include a value (p_{c}*g_{c}) obtained by multiplying the third interval p_{c} by the third vertical thickness g_{c}. When the first interval pₐ₁, the third interval p_{c}, and the second interval p_{b1} are sequentially increased, the cross-sectional area of the exhaust space formed in the first region R-1, the cross-section area of the exhaust space formed in each of the plurality of third regions R-3a and R-3b, and the cross-sectional area of the exhaust space formed in the second region R-2 may be sequentially increased.

Accordingly, the exhaust conductance of the exhaust space formed in the first region R-1, the exhaust conduction of the exhaust space formed in each of the plurality of third regions R-3a and R-3b, and the exhaust conductance of the exhaust space formed in the second region R-2 may be sequentially increased. Due to the difference in exhaust conductance by region as described above, the asymmetric exhaust capacity distribution described with reference to FIGS. 3 and 4 may be compensated.

In the above description with reference to FIGS. 10 to 11C, as the vertical levels of the bottom surfaces of the first region ring 120-1, the second region ring 120-2, and the plurality of third region rings 120-3a and 120-3b are implemented to be different, the exhaust conductance of the exhaust space formed in each of the first region R-1, the second region R-2, and the plurality of third regions R-3a and R-3b may be different. In the description with reference to FIGS. 12A to 12D, as the first interval pₐ₁, the second interval p_{b1}, and the third interval p_{c} are implemented to be different, the exhaust conductance of the exhaust space formed in each of the first region R-1, the second region R-2, and the plurality of third regions R-3a and R-3b may be different. For example, various methods of adjusting the exhaust conductance are separately described above for convenience of description, but the methods may be implemented in combination.

In addition, although it is shown that the top surface 110ts of the susceptor body 110 is divided into two regions or four regions based on the exhaust capacity distribution of the exhaust pump 212, this is merely for convenience of description, and embodiments are not limited thereto. The top surface 110ts of the susceptor body 110 may be divided into four or more regions based on the exhaust capacity distribution of the exhaust pump 212.

For example, returning to FIG. 9 again, each of the third-1 region R-3a and the third-2 region R-3b may be divided into n unit regions, where n is a natural number of 2 or greater, again. For example, each of the third-1 region R-3a and the third-2 region R-3b may include first to n^{th} unit regions, wherein the first to the n^{th} unit regions may include a region having a fan shape where the center CE of the top surface 110ts of the susceptor body 110 is the center of the fan. The cross-sectional area of the exhaust space formed in any one unit region, among the first to n^{th} unit regions, closest to the first region R-1 may be relatively small. The cross-sectional area of the exhaust space formed in any one unit region, among the first to n^{th} unit regions, closest to the second region R-2 may be relatively large. In addition, the cross-sectional area of the exhaust space formed in each of the first to n^{th} unit regions may be sequentially increased or decreased.

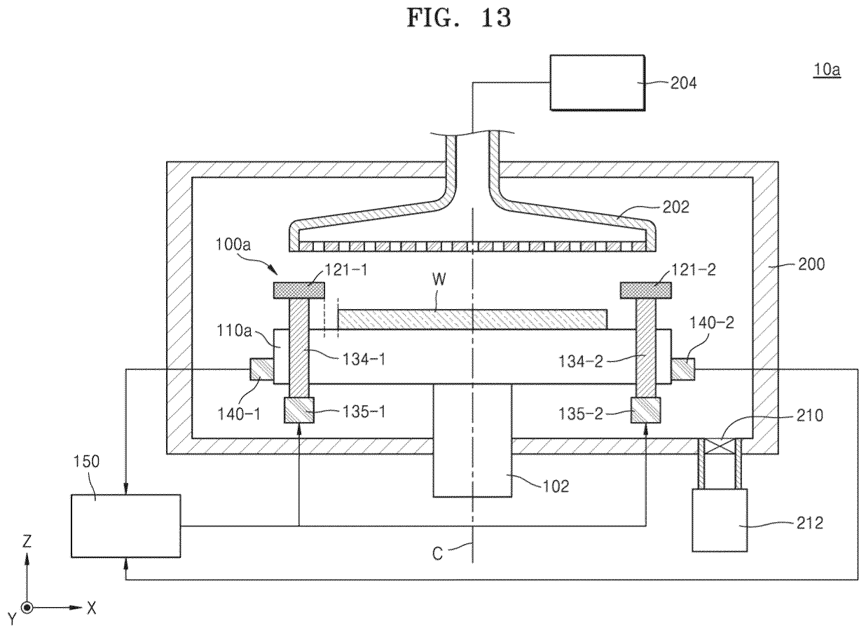

FIG. 13 is a cross-sectional view of a plasma processing apparatus 10a according to one or more embodiments. The descriptions that are substantially the same as those given with reference to FIGS. 1 and 2 are omitted. In the description with reference to FIG. 13, differences from the plasma processing apparatus 10 and the susceptor 100 of FIG. 1 are mainly described.

Referring to FIG. 13, the plasma processing apparatus 10a may further include a susceptor 100a and a controller 150.

The susceptor 100a may include a susceptor body 110a, a plurality of region rings (e.g., a first region ring 121-1 and a second region ring 121-2), a plurality of regions pins (e. g., a first region pin 134-1 and a second region pin 134-2), a plurality of region actuators (e.g., a first region actuator 135-1 and a second region actuator 135-2), and a plurality of region sensors (e.g., a first region sensor 140-1 and a second region sensor 140-2).

The number of region rings, the number of region pins, the number of region actuators, and the number of region sensors may correspond to the number of regions included in the top surface 110ts of the susceptor body 110a. However, in the description with reference to FIG. 13, it is assumed that the number of region rings, the number of region pins, the number of region actuators, and the number of region sensors are each 2, for convenience of description, and embodiments are not limited thereto.

The susceptor body 110a may receive each of the first region pin 134-1 and the second region pin 134-2. For example, the susceptor body 110a may include two holes penetrating from the bottom surface of the susceptor body 110a to the top surface 110ts of the susceptor body 110a, and the first region pin 134-1 and the second region pin 134-2 may be accommodated in the two holes, respectively.

The first region pin 134-1 may be connected to the first region ring 121-1 and the first region actuator 135-1. In addition, the second region pin 134-2 may be connected to the second region ring 121-2 and the second region actuator 135-2. The first region pin 134-1 and the second region pin 134-2 may support and fix the first region ring 121-1 and the second region ring 121-2, respectively.

The first region actuator 135-1 and the second region actuator 135-2 may drive the first region ring 121-1 and the second region ring 121-2 in the vertical direction, respectively. As an example, the first region actuator 135-1 and the second region actuator 135-2 may drive the first region ring 121-1 and the second region ring 121-2 in the vertical direction by vertically extending or contracting the first pin 134-1 and the second pin 134-2, respectively.

Each of the first region sensor 140-1 and the second region sensor 140-2 may be disposed on a sidewall of the susceptor body 110a. The vertical level of the first region sensor 140-1 may be the same as the vertical level of the second region sensor 140-2. However, in some embodiments, the vertical level of the first region sensor 140-1 may be different from the vertical level of the second region sensor 140-2. In addition, the vertical levels of the first region sensor 140-1 and the second region sensor 140-2 may be closer to the vertical level of the bottom surface of the susceptor body 110a than the vertical level of the top surface 110ts of the susceptor body 110a.

The first region sensor 140-1 may include a sensor for sensing an exhaust amount in the first region R-1, and the second region sensor 140-2 may include a sensor for sensing an exhaust amount in the second region R-2. According to one or more embodiments, each of the first region sensor 140-1 and the second region sensor 140-2 may be implemented as a flow sensor. In this case, the first region sensor 140-1 may sense the flow rate of particles flowing toward the exhaust port 210 in the first region R-1, and the second region sensor 140-2 may sense the flow rate of particles flowing toward the exhaust port 210 in the second region R-2.

The controller 150 may control the first region actuator 135-1 and the second region actuator 135-2. In addition, the controller 150 may obtain a sensing value from the first region sensor 140-1 and the second region sensor 140-2.

The controller 150 may be implemented in hardware, firmware, software, or any combination thereof. For example, the controller 150 may include a computing device, such as a workstation computer, a desktop computer, a laptop computer, a tablet computer, or the like. The controller 150 may include a simple controller, a complex processor, such as a microprocessor, a central processing unit (CPU), a graphics processing unit (GPU), or the like, a processor configured by software, dedicated hardware, or firmware. The controller 150 may be implemented by, for example, a general-purpose computer or application specific hardware, such as a digital signal process (DSP), a field programmable gate array (FPGA), an application-specific integrated circuit (ASIC), and the like. The controller 150 may be implemented as instructions stored on a machine-readable medium, which can be read and executed by one or more processors. The machine-readable medium may include any mechanism for storing and/or transmitting information in a machine-readable form (e.g., a computing device). For example, the machine-readable medium may include read-only memory (ROM), random-access memory (RAM), magnetic disk storage media, optical storage media, flash memory devices, electrical, optical, acoustical or other forms of propagated signals (e.g., carrier waves, infrared signals, or digital signals), and any other signals.

According to one or more embodiments, the controller 150 may identify the exhaust capacity distribution for the upper portion of the susceptor body 110a of the exhaust pump 212 based on the sensing value obtained from each of the first region sensor 140-1 and the second region sensor 140-2. For example, the controller 150 may obtain, based on a first sensing value of the first region sensor 140-1, first flow rate information of particles exhausted from the first region R-1 toward the exhaust port 210, and may obtain, based on a second sensing value of the second region sensor 140-2, second flow rate information of particles exhausted from the second region R-2 toward the exhaust port 220. The controller 150 may estimate the exhaust capacity distribution of the exhaust pump 212 based on the first flow rate information and the second flow rate information, and may identify, through the estimated exhaust capacity distribution, a degree of asymmetry of the exhaust capacity distribution.

In addition, the controller 150 may identify a first target vertical level of the bottom surface of the first region ring 121-1 and a second target vertical level of the bottom surface of the second region ring 121-2, based on the estimated exhaust capacity distribution. As described with reference to the above drawings, the cross-sectional area of the exhaust space formed in the region may increase as the vertical level of the bottom surface of the region ring increases. Therefore, when the exhaust capacity of the exhaust pump 212 for the second region R-2 is relatively greater than the exhaust capacity of the exhaust pump 212 for the first region R-1, the controller 150 may set the first target vertical level to be greater than the second target vertical level.

When the exhaust capacity of the exhaust pump 212 for the first region R-1 is relatively greater than the exhaust capacity of the exhaust pump 212 for the second region R-2, the controller 150 may set the first target vertical level to be less than the second target vertical level.

In addition, the controller 150 may determine, based on the identified degree of asymmetry of the exhaust capacity distribution, a difference between the first target vertical level and the second target vertical level. As an example, when the degree of asymmetry is very severe due to the relatively strong exhaust capacity of the exhaust pump 212 for the second region R-2 and the relatively weak exhaust capacity of the exhaust pump 212 for the first region R-1, the controller 150 may set the difference between the first target vertical level and the second target vertical level to be very large. When the degree of asymmetry is not relatively severe due to the relatively small difference between the exhaust capacity of the exhaust pump 212 for the second region R-2 and the exhaust capacity of the exhaust pump 212 for the first region R-1, the controller 150 may set the difference between the first target vertical level and the second target vertical level to be relatively small.

Then, the controller 150 may control each of the first region actuator 135-1 and the second region actuator 135-2 such that the bottom surfaces of the first region ring 121-1 and the second region ring 121-2 are arranged at the first target vertical level and the second target vertical level, respectively.

As the plasma processing apparatus 10a according to one or more embodiments includes the above-described configuration, the plasma processing apparatus 10a may dynamically respond to changes in the exhaust capacity distribution even when the exhaust capacity distribution of the exhaust pump 212 changes according to the change in process conditions. For example, the plasma processing apparatus 10a may identify the change in the exhaust capacity distribution of the exhaust pump 212 based on the sensing values of the plurality of region sensors (e.g., the first region sensor 140-1 and the second region sensor 140-2) and may dynamically respond to the change in exhaust capacity distribution by driving the plurality of region rings (e.g., the first region ring 121-1 and the second region ring 121-2) in the vertical direction through the plurality of actuators (e.g., the first region actuator 135-1 and the second region actuator 135-2).

As described above, the plasma processing apparatus according to one or more embodiments may compensate for the asymmetric exhaust capacity distribution of the exhaust pump 212 by setting the exhaust conductance of the exhaust space formed in each of the plurality of regions to be different.

While embodiments have been described with reference to the figures, it will be understood by those of ordinary skill in the art that various changes in form and details may be made therein without departing from the spirit and scope as defined by the following claims and their equivalents.

What is claimed is:

1. A susceptor comprising:
a susceptor body, a top surface of the susceptor body configured to support a wafer;
an edge ring spaced apart from the top surface of the susceptor body in a vertical direction, the edge ring having a circular ring shape; and
a plurality of support pins between the top surface of the susceptor body toward a bottom surface of the edge ring,
wherein a central axis of the edge ring is the same as a central axis of the susceptor body, an outer diameter of the edge ring is less than or equal to a diameter of the susceptor body, and an inner diameter of the edge ring is greater than a diameter of the wafer,
wherein a thickness of each support pin of the plurality of support pins in the vertical direction is greater than or equal to 0.3 mm, and
wherein a level of a top surface of the edge ring is greater than a level of a top surface of the wafer in the vertical direction.

2. The susceptor of claim 1, wherein the top surface of the susceptor body comprises a plurality of regions based on an exhaust capacity distribution of an exhaust pump for an upper region of the susceptor body,
wherein the edge ring comprises a plurality of region rings on the plurality of regions of the top surface of the susceptor body in the vertical direction, respectively,
wherein a level of a top surface of each region ring of the plurality of region rings is the same as each other,
wherein the plurality of support pins comprise a plurality of region support pins configured to support the plurality of region rings, respectively,
wherein a cross-sectional area of each exhaust space of a plurality of exhaust spaces respectively in the plurality of regions is determined based on a number of region support pins per unit area in the plurality of regions, a width of the region support pin in a horizontal direction, and a thickness of the region support pin in the vertical direction,
wherein a cross-sectional area of an exhaust space in a region having a first exhaust capacity is less than a cross-sectional area of an exhaust space in a region having a second exhaust capacity, among the plurality of regions, and
wherein the first exhaust capacity is greater than the second exhaust capacity.

3. The susceptor of claim 2, wherein a number of region support pins per unit area in the region having the first exhaust capacity is greater than a number of region support pins per unit area arranged in a region having the second exhaust capacity, among the plurality of regions.

4. The susceptor of claim 2, wherein the width of the region support pin in the horizontal direction in the region having the first exhaust capacity is greater than the width of the region support pin in the horizontal direction in the region having the second exhaust capacity, among the plurality of regions.

5. The susceptor of claim 2, wherein a level of a bottom surface of a region ring on the region having the first exhaust capacity is less than a level of a bottom surface of a region ring on the region having the second exhaust capacity, among the plurality of regions, in the vertical direction.

6. The susceptor of claim 2, wherein the plurality of regions comprise a first region and a second region,
wherein the first region is a fan-shaped region, the central axis of the susceptor body being a center of the fan and a first angle being a central angle of the fan,
wherein the second region is a fan-shaped region, the center of the susceptor body being a center of the fan and a second angle greater than the first angle being a central angle of the fan, and
wherein the exhaust capacity of the exhaust pump for the first region is greater than the exhaust capacity of the exhaust pump for the second region.

7. The susceptor of claim 6, wherein the first region and the second region comprise regions where a straight line in the horizontal direction from the central axis of the susceptor body toward a position of the exhaust pump is a line of symmetry of the fan, and
wherein the second region is a region, excluding the first region, of an entire region of the top surface of the susceptor body.

8. The susceptor of claim 6, wherein the first angle is determined based on a difference between the exhaust capacity of the exhaust pump for the first region and the exhaust capacity of the exhaust pump for the second region.

9. The susceptor of claim 6, wherein a difference between a level of a bottom surface of a first region ring on the first region and a level of a bottom surface of a second region ring on the second region, in the vertical direction, is determined based on a difference between the exhaust capacity of the exhaust pump for the first region and the exhaust capacity of the exhaust pump for the second region.

10. The susceptor of claim 6, wherein a difference between a number of first region support pins per unit area in the first region and a number of second region support pins per unit area in the second region is determined based on a difference between the exhaust capacity of the exhaust pump for the first region and the exhaust capacity of the exhaust pump for the second region.

11. The susceptor of claim 6, wherein a difference between a width of a first region support pin in the first region and a width of a second region support pin arranged in the second region, in the horizontal direction, is determined based on a difference between the exhaust capacity of the exhaust pump for the first region and the exhaust capacity of the exhaust pump for the second region.

12. The susceptor of claim 6, wherein the plurality of regions further comprise a third region,
wherein the third region is between the first region and the second region,
wherein the third region is a fan-shaped region, the central axis of the susceptor body being the center of the fan and a third angle being a central angle of the fan,
wherein the exhaust capacity of the exhaust pump for the third region is less than that of the exhaust pump for the first region and is greater than that of the exhaust pump for the second region, and
wherein the third angle is half of an angle obtained by subtracting the first angle and the second angle from 360 degrees.

13. A plasma processing apparatus comprising:
a housing comprising a plasma processing space;
a susceptor inside the housing and configured to support a wafer;
an exhaust port spaced apart from a central axis of the housing in a horizontal direction, at a level lower than a level of the wafer in a vertical direction, and passing through a portion of the housing; and
an exhaust pump configured to suction particles inside the housing through the exhaust port,
wherein the susceptor comprises:
a susceptor body;
an edge ring on the susceptor body, a central axis of the edge ring being aligned with a central axis of the susceptor body; and
a plurality of support pins between a top surface of the susceptor body and a bottom surface of the edge ring,
wherein an outer diameter of the edge ring is equal to or less than a diameter of the susceptor body, and
wherein particles inside the housing are configured to be exhausted through an exhaust space formed by a top surface of the susceptor body, a bottom surface of the edge ring, and the plurality of support pins.

14. The plasma processing apparatus of claim 13, wherein the top surface of the susceptor body comprises a plurality of regions based on the exhaust capacity distribution of the exhaust pump for an upper region of the susceptor body,
wherein each of the plurality of regions is a fan-shaped region, the central axis of the susceptor body being a center of the fan,
wherein the edge ring comprises a plurality of region rings on the plurality of regions, respectively,
wherein the plurality of support pins comprise a plurality of region support pins in each region of the plurality of regions,
wherein a cross-sectional area of each of a plurality of exhaust spaces in the plurality of regions is determined based on a number of region support pins per unit area in the plurality of regions, a width of the region support pin in the horizontal direction, and a thickness of the region support pin in the vertical direction,
wherein a cross-sectional area of an exhaust space in a region having a first exhaust capacity is less than a cross-sectional area of an exhaust space in a region having a second exhaust capacity, among the plurality of regions, and
wherein the first exhaust capacity is greater than the second exhaust capacity.

15. The plasma processing apparatus of claim 14, wherein, among the plurality of regions, a width of the region support pin in the region having the first exhaust capacity is greater than a width of the region support pin arranged in the region having the second exhaust capacity in the horizontal direction.

16. The plasma processing apparatus of claim 14, wherein, among the plurality of regions, a number of region support pins per unit area in the region having the first exhaust capacity is greater than a number of region support pins per unit area in the region having the second exhaust capacity.

17. The plasma processing apparatus of claim 14, wherein the plurality of regions comprise a first region and a second region,
wherein the first region is a fan-shaped region, the central axis of the susceptor body being the center of the fan and a first angle being a central angle of the fan,
wherein the second region is a fan-shaped region, the central axis of the susceptor body being the center of the fan and a second angle greater than the first angle being a central angle of the fan, and
wherein the exhaust capacity of the exhaust pump for the first region is greater than the exhaust capacity of the exhaust pump for the second region.

18. The plasma processing apparatus of claim 17, wherein the plurality of regions further comprise a third region,
wherein the third region is between the first region and the second region,
wherein the third region is a fan-shaped region, the central axis of the susceptor body being the center of the fan and a third angle being a central angle of the fan,
wherein the exhaust capacity of the exhaust pump for the third region is less than that of the exhaust pump for the first region and greater than that of the exhaust pump for the second region, and
wherein the third angle is half of an angle obtained by subtracting the first angle and the second angle from 360 degrees.

19. The plasma processing apparatus of claim 18, wherein the third angle is less than the second angle, and twice the third angle is greater than the first angle.

20. A plasma processing apparatus comprising:
a housing;
a susceptor inside the housing;
an exhaust port spaced apart from a central axis of the housing in a horizontal direction and penetrating a portion of a bottom surface of the housing; and
an exhaust pump configured to suction particles inside the housing through the exhaust port,
wherein the susceptor comprises:
a susceptor body; and
a plurality of region rings respectively on a plurality of regions included in a top surface of the susceptor body, a center of each region of the plurality of regions being aligned with a central axis of the susceptor body,
wherein each region of the plurality of regions is a region based on an exhaust capacity distribution of the exhaust pump for an upper region of the susceptor body,
wherein an exhaust capacity distribution of the exhaust pump is determined based on a relative position of the exhaust port with respect to the susceptor body,
wherein a level of a bottom surface of the region ring on the region having a first exhaust capacity is less than a level of a bottom surface of the region ring on the region having a second exhaust capacity, among the plurality of regions, in the vertical direction, and
wherein the first exhaust capacity is greater than the second exhaust capacity.
